(19) United States
(12) Patent Application Publication
(10) Pub. No.: US 2025/0204151 A1
(43) Pub. Date: Jun. 19, 2025

(54) DISPLAY APPARATUS

(71) Applicant: Samsung Display Co., Ltd., Yongin-Si (KR)

(72) Inventors: Kyoungseok Son, Yongin-si (KR); Youngoo Kim, Yongin-si (KR); Jaybum Kim, Yongin-si (KR); Seunghun Lee, Yongin-si (KR)

(21) Appl. No.: 18/806,699

(22) Filed: Aug. 16, 2024

(30) Foreign Application Priority Data
Dec. 19, 2023 (KR) 10-2023-0186146

(51) Int. Cl. H10K 59/121; H01L 27/12; H10K 59/12; H10K 59/131; H10K 102/00

(52) U.S. Cl. CPC H10K 59/1213; H10K 59/1201; H10K 59/1216; H10K 59/131; H10D 86/423; H10D 86/60; H10K 2102/351

(57) ABSTRACT

A display apparatus is disclosed that includes a substrate, a first thin-film transistor, a second thin-film transistor, and a lower conductive layer. The first thin-film transistor is located on the substrate and includes a first semiconductor layer and a first gate electrode. The second thin-film transistor is located on the substrate and includes a second semiconductor layer, a second gate electrode, a lower electrode, and an upper electrode. The lower conductive layer is located between the substrate and the first semiconductor layer. A first angle between a channel region of the first semiconductor layer and the substrate is different from a second angle between a channel region of the second semiconductor layer and the substrate. The first gate electrode and the second gate electrode are located on a same layer.

### CROSS-REFERENCE TO RELATED APPLICATION

This application is based on and claims priority under 35 U.S.C. § 119 to Korean Patent Application No. 10-2023-0186146, filed on Dec. 19, 2023, in the Korean Intellectual Property Office, the disclosure of which is incorporated by reference herein in its entirety.

### BACKGROUND

### 1. Field

One or more embodiments relate to a display apparatus.

### 2. Description of the Related Art

In general, a display apparatus includes light-emitting elements and pixel circuits for controlling electrical signals applied to the light-emitting elements. The pixel circuits include a thin-film transistor (TFT), a capacitor, and a plurality of wirings. The light-emitting elements emit light in response to electrical signals applied from the wirings.

Research on high integration and high reliability of such display apparatuses is actively being conducted.

### SUMMARY

Embodiments may provide a display apparatus that is highly integrated and may display a high-quality image. However, the embodiments are examples and do not limit the scope of the disclosure.

Additional aspects will be set forth in part in the description which follows and, in part, will be apparent from the description, or may be learned by practice of the presented embodiments.

According to one or more embodiments, a display apparatus includes a substrate, a first thin-film transistor located on the substrate and including a first semiconductor layer and a first gate electrode, and a second thin-film transistor located on the substrate and including a second semiconductor layer and a second gate electrode, wherein a first angle between a channel region of the first semiconductor layer and the substrate is different from a second angle between a channel region of the second semiconductor layer and the substrate, wherein the first gate electrode and the second gate electrode are located on a same layer.

The first angle may be 0° to 5°, and the second angle may be 20° to 90°.

The display apparatus may further include a lower conductive layer located between the substrate and the first semiconductor layer, wherein the second thin-film transistor is connected to a bottom surface of the second semiconductor layer and further includes a lower electrode and an upper electrode located on different layers, and the lower conductive layer is located on a same layer as the lower electrode.

A central portion of the second semiconductor layer may be connected to the lower electrode, and a peripheral portion of the second semiconductor layer may be connected to the upper electrode.

The display apparatus may further include a first insulating layer located between the lower electrode and the upper electrode, wherein the first insulating layer includes a first opening that extends to the lower electrode, and at least a part of the second semiconductor layer is located in the first opening.

The display apparatus may further include a second insulating layer covering the second semiconductor layer, wherein a thickness of the second insulating layer is less than a thickness of the first insulating layer.

The display apparatus may further include a storage capacitor including a first capacitor electrode and a second capacitor electrode, wherein the first capacitor electrode is located on a same layer as the first gate electrode and the second gate electrode.

Each of the first semiconductor layer and the second semiconductor layer may include an oxide semiconductor.

The display apparatus may further include a third thin-film transistor located on the substrate and including a third semiconductor layer and a third gate electrode, wherein each of the first semiconductor layer and the second semiconductor layer includes an oxide semiconductor, and the third semiconductor layer includes a silicon semiconductor.

The third gate electrode may be located above the third semiconductor layer and below a first insulating layer, and the first semiconductor layer may be located above the first insulating layer.

According to one or more embodiments, a display apparatus includes a substrate, a first insulating layer located on the substrate and including a first opening, a first thin-film transistor including a first semiconductor layer and a first gate electrode, the first semiconductor layer being located on a top surface of the first insulating layer, a second thin-film transistor including a second semiconductor layer at least partially located in the first opening, a lower electrode located under the first insulating layer, an upper electrode located over the first insulating layer, and a second gate electrode located on the second semiconductor layer, and a second insulating layer covering the first semiconductor layer and the second semiconductor layer, wherein the first gate electrode and the second gate electrode are located on the second insulating layer.

An angle between an inner wall of the first opening and a top surface of the substrate may be 20° to 90°.

The display apparatus may further include a lower conductive layer located between the substrate and the first semiconductor layer, wherein the lower electrode is located on a same layer as the lower conductive layer.

A central portion of the second semiconductor layer may be connected to the lower electrode, and a peripheral portion of the second semiconductor layer may be connected to the upper electrode.

A thickness of the second insulating layer may be less than a thickness of the first insulating layer.

Each of the first semiconductor layer and the second semiconductor layer may include an oxide semiconductor.

The display apparatus may further include a storage capacitor including a first capacitor electrode and a second capacitor electrode, wherein the first capacitor electrode is located on a same layer as the first gate electrode and the second gate electrode.

The display apparatus may further include a third thin-film transistor located on the substrate and including a third semiconductor layer and a third gate electrode, wherein each of the first semiconductor layer and the second semiconductor layer includes an oxide semiconductor, and the third semiconductor layer includes a silicon semiconductor.

The third gate electrode may be located above the third semiconductor layer and below a first insulating layer, and the first semiconductor layer may be located above the first insulating layer.

The third thin-film transistor may be a driving thin-film transistor.

### BRIEF DESCRIPTION OF THE DRAWINGS

The above and other aspects, features, and advantages of certain embodiments will be more apparent from the following description taken in conjunction with the accompanying drawings, in which:

FIG. 1 is a plan view schematically illustrating a display apparatus, according to an embodiment;

FIGS. 2 and 3 are equivalent circuit diagrams illustrating a sub-pixel included in a display apparatus, according to an embodiment;

FIG. 4 is a schematic cross-sectional view taken along line I-I′ of FIG. 1;

FIGS. 5, 6, 7, 8, 9, 10, 11, 12, 13, and 14 are cross-sectional views schematically illustrating parts of a process of manufacturing a display apparatus, according to an embodiment;

FIG. 15 is a cross-sectional view schematically illustrating a display apparatus, according to an embodiment;

FIG. 16 is a cross-sectional view schematically illustrating a display apparatus, according to an embodiment;

FIG. 17 is a cross-sectional view schematically illustrating a display apparatus, according to an embodiment;

FIG. 18 is a plan view schematically illustrating a part of a display apparatus, according to an embodiment; and

FIG. 19 is a plan view schematically illustrating a comparative example with respect to the embodiment of FIG. 18.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.” Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings, wherein the same or corresponding elements are denoted by the same reference numerals throughout and a repeated description thereof is omitted.

Although the terms “first,” “second,” etc. may be used to describe various elements, these elements should not be limited by these terms. These terms are only used to distinguish one clement from another.

As used herein, the singular forms “a,” “an,” and “the” are intended to include the plural forms as well, unless the context clearly indicates otherwise.

It will be further understood that the terms “comprises” and “comprising” used herein specify the presence of stated features or components, but do not preclude the presence or addition of one or more other features or components.

It will be further understood that, when a layer, region, or component is referred to as being “on” another layer, region, or component, it may be directly on the other layer, region, or component, or may be indirectly on the other layer, region, or component with intervening layers, regions, or components therebetween.

Sizes of components in the drawings may be exaggerated or reduced for convenience of explanation. For example, because sizes and thicknesses of components in the drawings are arbitrarily illustrated for convenience of explanation, the disclosure is not limited thereto.

It will be understood that when a layer, region, or component is referred to as being “connected,” the layer, the region, or the component may be directly connected or may be indirectly connected with intervening layers, regions, or components therebetween. For example, when layers, regions, or components are referred to as being “electrically connected,” the layers, the regions, or the components may be directly electrically connected, or may be indirectly electrically connected with intervening layers, regions, or components therebetween.

In the following embodiments, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

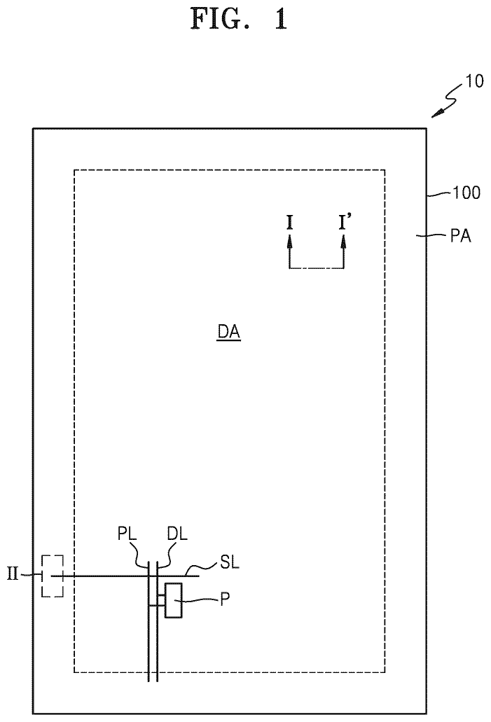

FIG. 1 is a plan view schematically illustrating a display apparatus, according to an embodiment;

Referring to FIG. 1, a substrate 100 of a display apparatus 10 may be divided into a display area DA and a peripheral area PA around the display area DA. The display apparatus 10 may provide a certain image by using light emitted from a plurality of pixels P located in the display area DA.

An edge of the display area DA may have a substantially rectangular or square shape. Accordingly, the substrate 100 may also have a substantially rectangular or square shape. An edge of the display area DA may have a circular shape, an elliptical shape, or a polygonal shape.

Although an organic light-emitting display apparatus is described as the display apparatus according to an embodiment, the display apparatus of the disclosure is not limited thereto. In another embodiment, the display apparatus of the disclosure may be a display apparatus such as an inorganic light-emitting display apparatus (or an inorganic electroluminescent (EL) display apparatus) or a quantum dot light-emitting display apparatus. For example, an emission layer of the light-emitting element included in the display apparatus may include an organic material or an inorganic material. Also, the display apparatus may include an emission layer and quantum dots located in a path of light emitted from the emission layer.

A plurality of pixels P are located in the display area DA. Each pixel may refer to a sub-pixel. Each pixel P may emit, for example, red light, green light, blue light, or white light.

Each pixel P may be connected to a pixel circuit including a thin-film transistor (TFT) and a storage capacitor. The pixel circuit may be connected to a scan line SL, a data line DL intersecting the scan line SL, and a driving voltage line PL. The scan line SL may extend in an x direction, and the data line DL and the driving voltage line PL may extend in a y direction.

Each pixel P may emit light by driving the pixel circuit, and the display area DA provides a certain image through light emitted from the pixels P. The pixel P in the specification may be defined as an emission area where red light, green light, blue light, or white light is emitted as described above.

The peripheral area PA is an area where the sub-pixels P are not located and an image is not provided. A printed circuit board including a built-in driving circuit unit for driving the pixels P, a power supply wiring, and a driving circuit unit, or a terminal unit to which a driver integrated circuit (IC) is connected may be located in the peripheral area PA.

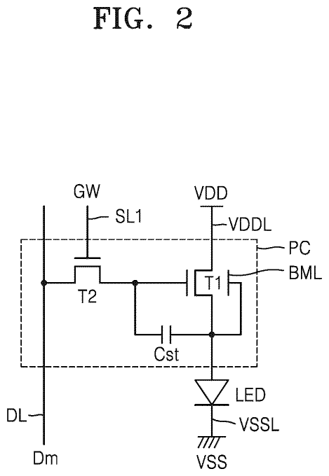

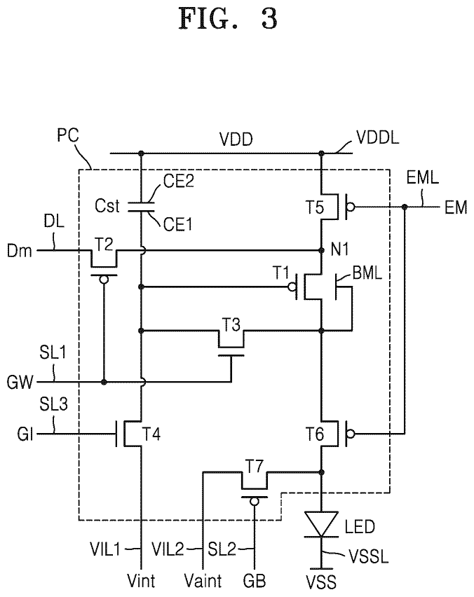

FIGS. 2 and 3 are equivalent circuit diagrams illustrating a sub-pixel included in a display apparatus, according to an embodiment.

Referring to FIG. 2, a light-emitting element LED corresponding to a sub-pixel may be electrically connected to a pixel circuit PC, and the pixel circuit PC may include a first transistor T1, a second transistor T2, and a storage capacitor Cst. The pixel circuit PC may be electrically connected to a signal line and a voltage line. The signal line may include a gate line such as a first scan line SL1 and a data line DL, and the voltage line may include a first voltage line VDDL.

The second transistor T2 may be electrically connected to the first scan line SL1 and the data line DL. The first scan line SL1 may provide a first scan signal GW1 to a gate electrode of the second transistor T2. The second transistor T2 may transmit a data signal Dm input from the data line DL to the first transistor T1 according to the first scan signal GW1 input from the first scan line SL1.

The storage capacitor Cst may be electrically connected to the second transistor T2 and the first transistor T1 and may store a voltage corresponding to the data signal Dm.

The first transistor T1 is a driving transistor and may control driving current flowing through the light-emitting element LED. The first transistor T1 may be connected to the first voltage line VDDL and the storage capacitor Cst. The first transistor T1 may control the driving current flowing through the light-emitting clement LED from the first voltage line VDDL in response to a value of the voltage stored in the storage capacitor Cst. A lower conductive layer BML may be located under the first transistor T1. The lower conductive layer BML may be connected to a first electrode of the light-emitting clement LED and the storage capacitor Cst. However, the disclosure is not limited thereto. The lower conductive layer BML may be connected to the first voltage line VDDL to receive a constant voltage.

The light-emitting element LED may emit light having a certain luminance due to the driving current. The first electrode of the light-emitting element LED may be electrically connected to the first transistor T1, and a second electrode of the light-emitting element LED may be electrically connected to a second voltage line VSSL that supplies a second power supply voltage VSS.

Each of the first transistor T1 and the second transistor T2 may be an N-type transistor. For example, each of the first transistor T1 and the second transistor T2 may include a semiconductor layer including oxide. In some embodiments, the first transistor T1 may be a horizontal channel transistor including a semiconductor layer parallel to a top surface of a substrate, and the second transistor T2 may be a vertical channel transistor including a semiconductor layer having a certain angle with respect to the top surface of the substrate.

Although the pixel circuit PC includes two transistors and one storage capacitor in FIG. 2, in another embodiment, the pixel circuit PC may include three or more transistors.

Referring to FIG. 3, a pixel circuit PC may include a first transistor T1, a second transistor T2, a third transistor T3, a fourth transistor T4, a fifth transistor T5, a sixth transistor T6, a seventh transistor T7, and a storage capacitor Cst.

The pixel circuit PC is electrically connected to signal lines and voltage lines. The signal lines may include gate lines such as a first scan line SL1, a second scan line SL2, a third scan line SL3, a fourth scan line SL4, and an emission control line EML, and a data line DL. The voltage lines may include first and second initialization voltage lines VIL1 and VIL2, and a first voltage line VDDL.

The first voltage line VDDL may transmit a first power supply voltage VDD to the first transistor T1. The first initialization voltage line VIL1 may transmit a first initialization voltage Vint for initializing the first transistor T1 to the pixel circuit PC. The second initialization voltage line VIL2 may transmit a second initialization voltage Vaint for initializing a first electrode of a light-emitting element LED to the pixel circuit PC.

The first transistor T1 may be electrically connected to the first voltage line VDDL via the fifth transistor T5, and may be electrically connected to the light-emitting element LED via the sixth transistor T6. The first transistor T1 functions as a driving transistor, and receives a data signal Dm according to a switching operation of the second transistor T2 and supplies driving current to the light-emitting element LED.

A lower conductive layer BML may be located under the first transistor T1. The lower conductive layer BML may be connected to one electrode of the third transistor T3 or one electrode of the sixth transistor T6. When the one electrode of the third transistor T3 and the one electrode of the sixth transistor T6 are located on the same layer as the lower conductive layer BML, the electrodes do not need to be connected to a connection member located on another layer through a contact hole, thereby enabling high integration. The second transistor T2 is a data write transistor and is electrically connected to the first scan line SL1 and the data line DL. The second transistor T2 is electrically connected to the first voltage line VDDL via the fifth transistor T5. The second transistor T2 is turned on according to a first scan signal GW received through the first scan line SL1 to perform a switching operation of transmitting the data signal Dm received through the data line DL to a first node N1.

The third transistor T3 is electrically connected to the first scan line SL1 and is electrically connected to the light-emitting element LED via the sixth transistor T6. The third transistor T3 may be turned on according to the first scan signal GW received through the first scan line SL1 to diode-connect the first transistor T1.

The fourth transistor T4 is a first initialization transistor and is electrically connected to the third scan line SL3 and the first initialization voltage line VIL1. The fourth transistor T4 is turned on according to a third scan signal G1 received through the third scan line SL3 to initialize a voltage of a gate electrode of the first transistor T1 by transmitting the first initialization voltage Vint from the first initialization voltage line VIL1 to the gate electrode of the first transistor T1. The third scan signal G1 may correspond to a first scan signal of another pixel circuit located in a previous row of the pixel circuit PC.

The fifth transistor T5 may be an operation control transistor, and the sixth transistor T6 may be an emission control transistor. The fifth transistor T5 and the sixth transistor T6 are electrically connected to the emission control line EML, and are simultaneously turned on according to an emission control signal EM received through the emission control line EML to form a current path through which the driving current may flow from the first voltage line VDDL to the light-emitting element LED.

The seventh transistor T7 is a second initialization transistor and may be electrically connected to the second scan line SL2, the second initialization voltage line VIL2, and the sixth transistor T6. The seventh transistor T7 may be turned on according to a second scan signal GB received through the second scan line SL2 to initialize the first electrode of the light-emitting element LED by transmitting the second initialization voltage Vaint from the second initialization voltage line VIL2 to the first electrode of the light-emitting element LED.

The storage capacitor Cst includes a first capacitor electrode CE1 and a second capacitor electrode CE2. The first capacitor electrode CE1 is electrically connected to the gate electrode of the first transistor T1, and the second capacitor electrode CE2 is electrically connected to the first voltage line VDDL. The storage capacitor Cst may maintain a voltage applied to the gate electrode of the first transistor T1 by storing and maintaining a voltage corresponding to a voltage difference between the first voltage line VDDL and the gate electrode of the first transistor T1.

Although the third transistor T3 and the fourth transistor T4 from among the plurality of transistors (e.g., T1 to T7) are N-type transistors and the remaining transistors are P-type transistors in FIG. 3, the disclosure is not limited thereto. Various modifications may be made. For example, a transistor other than the third transistor T3 and the fourth transistor T4 from among the plurality of transistors (e.g., T1 to T7) may be an N-type transistor.

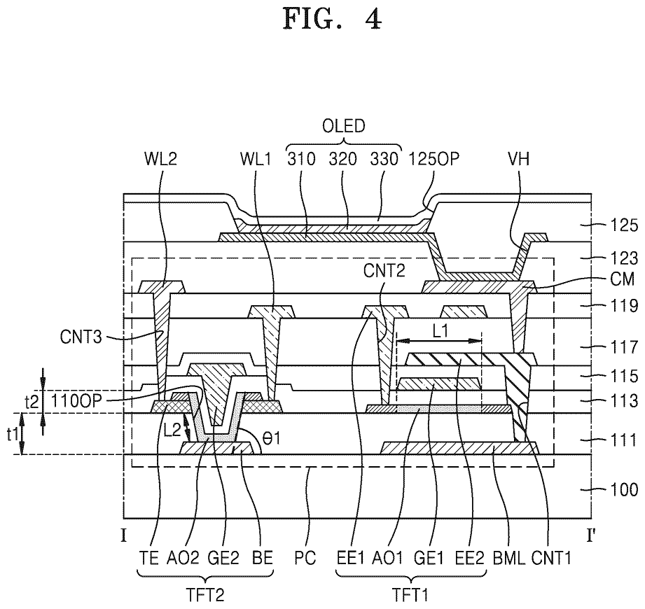

In an embodiment, at least one of the plurality of transistors (e.g., T1 through T7) may include a semiconductor layer including oxide, and the remaining transistors may include a semiconductor layer including silicon. For example, each of the third transistor T3 and the fourth transistor T4 may include an oxide semiconductor layer, and the remaining transistors may include a silicon semiconductor layer. However, the disclosure is not limited thereto. All of the plurality of transistors (e.g., T1 to T7) may include an oxide semiconductor layer. FIG. 4 is a schematic cross-sectional view taken along line I-I′ of FIG. 1.

Referring to FIG. 4, in the display apparatus according to an embodiment, a pixel circuit PC may be located on the substrate 100, and an organic light-emitting diode OLED may be located as a light-emitting element connected to the pixel circuit PC.

The pixel circuit PC according to the present embodiment includes a first thin-film transistor TFT1 that is a horizontal-type transistor and a second thin-film transistor TFT2 that is a vertical-type transistor.

A horizontal-type transistor in the specification refers to a thin-film transistor in which a current flow direction through a semiconductor layer is substantially parallel to a top surface of the substrate 100. That is, an angle between a channel region of the semiconductor layer of the horizontal-type transistor and the top surface of the substrate 100 may range from about 0° to about 5°.

A vertical-type transistor in the specification refers to a thin-film transistor in which a current flow direction through a semiconductor layer has a certain angle with respect to the top surface of the substrate 100. That is, an angle between a channel region of the semiconductor layer of the vertical-type transistor and the top surface of the substrate 100 may range from about 20° to about 90°, preferably from about 45° to about 90°.

The first thin-film transistor TFT1 is a horizontal-type transistor and includes a first semiconductor layer AO1 and a first gate electrode GE1 insulated from the first semiconductor layer AO1. The first thin-film transistor TFT1 may further include a first electrode EE1 and a second electrode EE2 connected to first and second sides, respectively, of a channel region of the first semiconductor layer AO1. One of the first electrode EE1 and the second electrode EE2 may be a source electrode and the other may be a drain electrode. A lower conductive layer BML overlapping the first semiconductor layer AO1 may be located under the first thin-film transistor TFT1. The lower conductive layer BML may prevent external light from reaching the first semiconductor layer AO1. The lower conductive layer BML may function as a lower gate electrode. Alternatively, the lower conductive layer BML may be connected to various wirings to provide a voltage so that driving of the first thin-film transistor TFT1 may be stabilized.

The first semiconductor layer AO1 is provided substantially parallel to the top surface of the substrate 100. An angle between the first semiconductor layer AO1 and the top surface of the substrate 100 may range from about 0° to about 5°. A first angle between the channel region of the first semiconductor layer and the substrate may be different from a second angle θ between a channel region of a second semiconductor layer and the substrate. The first semiconductor layer AO1 may overlap the first gate electrode GE1, and a length L1 of the channel region of the first semiconductor layer AO1 may be determined by a width of the first gate electrode GE1.

The first thin-film transistor TFT1 may function as a driving thin-film transistor. Because a horizontal-type transistor has a wider driving range than a vertical-type transistor and high process reliability, when the first thin-film transistor TFT1 that is a horizontal-type transistor is used as a driving thin-film transistor, the reliability of the display apparatus may be improved.

The second thin-film transistor TFT2 is a vertical-type transistor and includes a second semiconductor layer AO2 and a second gate electrode GE2 insulated from the second semiconductor layer AO2. The second thin-film transistor TFT2 may include a lower electrode BE and an upper electrode TE. One of the lower electrode BE and the upper electrode TE may be a source electrode and the other may be a drain electrode. The lower electrode BE and the upper electrode TE may contact a bottom surface of the second semiconductor layer AO2.

The lower electrode BE may contact a central portion of the second semiconductor layer AO2. The upper electrode TE may be located above the lower electrode BE and may contact a peripheral portion of the second semiconductor layer AO2. A channel region may be formed in the second semiconductor layer AO2 located between the upper electrode TE and the lower electrode BE. The channel region of the second semiconductor layer AO2 has a certain angle with respect to the top surface of the substrate 100. An angle θ1 between the channel region of the second semiconductor layer AO2 and the top surface of the substrate 100 may range from about 20° to about 90°, preferably from about 45° to about 90°. A length L2 of the channel region of the second semiconductor layer AO2 may be a length between the lower electrode BE and the upper electrode TE, and may be adjusted by a thickness t1 of a first insulating layer 111.

The second thin-film transistor TFT2 may be a switching thin-film transistor. As the second thin-film transistor TFT2 that is a vertical-type transistor is employed, a length of the channel region may be vertically adjusted, thereby saving space and enabling high integration.

In the present embodiment, the first gate electrode GE1 of the first thin-film transistor TFT1 and the second gate electrode GE2 of the second thin-film transistor TFT2 may be formed of the same material on the same layer. Also, the lower conductive layer BML and the lower electrode BE of the second thin-film transistor TFT2 may be formed of the same material on the same layer. Through this configuration, a process time and process costs may be minimized.

Hereinafter, a structure elements included in the display apparatus of the present embodiment are stacked will be described.

The substrate 100 may be formed of an insulating material such as glass, quartz, or a polymer resin. The substrate 100 may be a rigid substrate, or a flexible substrate that is bendable, foldable, or rollable. The substrate 100 may have a single or multi-layer structure including the above material, and when the substrate 100 has a multi-layer structure, the substrate 100 may further include an inorganic layer. In some embodiments, the substrate 100 may have a structure including an organic material, an inorganic material, and an organic material.

The lower conductive layer BML and the lower electrode BE of the second thin-film transistor TFT2 are located on the substrate 100. Each of the lower conductive layer BML and the lower electrode BE may include a conductive material including molybdenum (Mo), aluminum (Al), copper (Cu), or titanium (Ti), and may have a single or multi-layer structure including the above material. An insulating layer such as a barrier layer may be further located between the substrate 100 and the lower conductive layer BML or between the substrate 100 and the lower electrode BE. In an embodiment, the lower conductive layer BML may be connected to the lower electrode BE of the second thin-film transistor TFT2. In this case, the lower conductive layer BML is located on the same layer as the lower electrode BE, and thus, may be directly connected to the lower electrode BE. When the lower conductive layer BML and the lower electrode BE are located on different layers, because the lower conductive layer BML and the lower electrode BE should be connected to each other through a contact hole, a space where the contact hole is to be formed may be additionally required. In the present embodiment, because the contact hole is not required, high integration may be possible. The first insulating layer 111 may be provided on the substrate 100 to cover the lower conductive layer BML and the lower electrode BE. The first insulating layer 111 may include an inorganic material such as oxide or nitride, an organic material, or a combination of an organic material and an inorganic material, and may have a single or multi-layer structure including an inorganic material and an organic material. In some embodiments, the first insulating layer 111 may be formed of silicon oxide (SiO₂), silicon nitride (SiN_{X}), or silicon oxynitride (SiOₓN_{y}).

The first insulating layer 111 may be located between the lower electrode BE and the upper electrode TE to insulate the lower electrode BE from the upper electrode TE. That is, the lower electrode BE may be located under the first insulating layer 111, and the upper electrode TE may be located over the first insulating layer 111. Also, the channel length L2 of the second semiconductor layer AO2 may be adjusted by using the thickness t1 of the first insulating layer 111. The thickness t1 of the first insulating layer 111 may be adjusted to hundreds to thousands of Å. In some embodiments, the channel length L2 of the second semiconductor layer AO2 may be less than the channel length L1 of the first semiconductor layer AO1. The first insulating layer 111 may be located between the lower conductive layer BML and the first semiconductor layer AO1 to insulate the lower conductive layer BML from the first semiconductor layer AO1.

The first insulating layer 111 may include an opening 111OP that extends to the lower electrode BE. The upper electrode TE may be located around the opening 111OP on the first insulating layer 111.

The upper electrode TE may be located on the first insulating layer 111 and may surround at least a part of the opening 111OP defined in the first insulating layer 111. Portions of the upper electrode TE located on both sides of the opening 111OP may be connected to each other. The upper electrode TE may include a conductive material including molybdenum (Mo), aluminum (Al), copper (Cu), or titanium (Ti), and may have a single or multi-layer structure including the above material.

The first semiconductor layer AO1 of the first thin-film transistor TFT1 may be provided on the first insulating layer 111 to overlap the lower conductive layer BML. The second semiconductor layer AO2 of the second thin-film transistor TFT2 may be located on a top surface of the upper electrode TE and in the opening 111OP of the first insulating layer 111. The second semiconductor layer AO2 may contact the lower electrode BE through the opening 111OP. The second semiconductor layer AO2 located between the lower electrode BE and the upper electrode TE may be a channel region, and the length L2 of the channel region may be adjusted by the thickness of the first insulating layer 111. The angle θ1 between the channel region of the second semiconductor layer AO2 and the top surface of the substrate 100 may range from about 20° to about 90°, preferably from about 45° to about 90°. Alternatively, the angle θ1 between an inner surface of the opening 111OP and the top surface of the substrate 100 may range from about 20° to about 90°, preferably from about 45° to about 90°.

The first semiconductor layer AO1 and the second semiconductor layer AO2 may be formed of the same material. Each of the first semiconductor layer AO1 and the second semiconductor layer AO2 may include an oxide semiconductor. For example, each of the first semiconductor layer AO1 and the second semiconductor layer AO2 may include an oxide of a material selected from group 12, 13, and 14 metal elements such as zinc (Zn), indium (In), gallium (Ga), tin (Sn), cadmium (Cd), germanium (Ge), or hafnium (Hf), and a combination thereof. In some embodiments, the first semiconductor layer AO1 and the second semiconductor layer AO2 may be formed of a Zn oxide-based material such as Zn oxide, In—Zn oxide, or Ga—In—Zn oxide. For example, the first semiconductor layer AO1 and the second semiconductor layer AO2 may be formed of, for example, zinc oxide (ZnO), zinc-tin oxide (ZTO), zinc-indium oxide (ZIO), indium oxide (InO), titanium oxide (TiO), indium-gallium-zinc oxide (IGZO), or indium-zinc-tin oxide (IZTO).

A second insulating layer 113 is provided on the substrate 100 to cover the first semiconductor layer AO1 and the second semiconductor layer AO2. The second insulating layer 113 may be formed of silicon oxide (SiO₂), silicon nitride (SiNₓ), silicon oxynitride (SiON), aluminum oxide (Al₂O₃), titanium oxide (TiO₂), tantalum oxide (Ta₂O₅), or hafnium oxide (HfO2).

A part of the second insulating layer 113 may be located in the opening 111OP of the first insulating layer 111 along a shape of the second semiconductor layer AO2. A thickness t2 of the second insulating layer 113 may be less than the thickness t1 of the first insulating layer 111.

The first gate electrode GE1 and the second gate electrode GE2 may be located on the second insulating layer 113. The first gate electrode GE1 may overlap the first semiconductor layer AO1. The length L1 of the channel region of the first semiconductor layer AO1 may be determined by a width of the first gate electrode GE1. That is, a portion of the first semiconductor layer AO1 overlapping the first gate electrode GE1 may be the channel region.

The second gate electrode GE2 may overlap the second semiconductor layer AO2. Also, the second gate electrode GE2 may overlap the lower electrode BE. A part of the second gate electrode GE2 may be located in the opening 111OP of the first insulating layer 111.

The first gate electrode GE1 and the second gate electrode GE2 may be formed of the same material on the same layer. Each of the first gate electrode GE1 and the second gate electrode GE2 may include a conductive material including molybdenum (Mo), aluminum (Al), copper (Cu), or titanium (Ti), and may have a single or multi-layer structure including the above material.

A third insulating layer 115 may be provided on the substrate 100 to cover the first gate electrode GE1 and the second gate electrode GE2. The third insulating layer 115 may be formed of silicon oxide (SiO₂), silicon nitride (SiNₓ), silicon oxynitride (SiON), aluminum oxide (Al₂O₃), titanium oxide (TiO₂), tantalum oxide (Ta₂O₅), or hafnium oxide (HfO₂).

The second electrode EE2 may be located on the third insulating layer 115. The second electrode EE2 may be connected to the first semiconductor layer AO1. The second electrode EE2 may be a source electrode or a drain electrode of the first thin-film transistor TFT1. A part of the second electrode EE2 may overlap the first gate electrode GE1 to form a capacitor. The second electrode EE2 may be connected to a source region or a drain region of the first semiconductor layer AO1 through a first contact hole CNT1 passing through the third insulating layer 115 and the second insulating layer 113. The first contact hole CNT1 may extend through the first insulating layer 111, and in this case, the second electrode EE2 may be connected to the lower conductive layer BML.

The second electrode EE2 may include a conductive material including molybdenum (Mo), aluminum (Al), copper (Cu), or titanium (Ti), and may have a single or multi-layer structure including the above material.

A fourth insulating layer 117 may be provided on the substrate 100 to cover the second electrode EE2. The fourth insulating layer 117 may be formed of silicon oxide (SiO₂), silicon nitride (SiNₓ), silicon oxynitride (SiON), aluminum oxide (Al₂O₃), titanium oxide (TiO₂), tantalum oxide (Ta₂O₅), or hafnium oxide (HfO₂).

The first electrode EE1 and a first wiring WL1 may be located on the fourth insulating layer 117. The first electrode EE1 may be a source electrode or a drain electrode of the first thin-film transistor TFT1. The first electrode EE1 may be connected to the source region or the drain region of the first semiconductor layer AO1 through a second contact hole CNT2 passing through the fourth insulating layer 117 and the third insulating layer 115. The first electrode EE1 may be a part of a wiring such as a driving voltage line. The first wiring WL1 may be connected to the upper electrode TE of the second thin-film transistor TFT2. The first wiring WL1 may be a wiring that transmits a data signal or the like. Each of the first electrode EE1 and the first wiring WLI may include molybdenum (Mo), aluminum (Al), copper (Cu), or titanium (Ti), and may have a single or multi-layer structure.

The fifth insulating layer 119 may be provided on the substrate 100 to cover the first electrode EE1 and the first wiring WL1. The fifth insulating layer 119 may be formed of silicon oxide (SiO₂), silicon nitride (SiNₓ), silicon oxynitride (SiON), aluminum oxide (Al₂O₃), titanium oxide (TiO₂), tantalum oxide (Ta₂O₅), or hafnium oxide (HfO₂).

A second wiring WL2 and a connection electrode CM may be located on the fifth insulating layer 119. The second wiring WL2 may be connected to the upper electrode TE of the second thin-film transistor TFT2. The second wiring WL2 may be connected to the upper electrode TE through a third contact hole CNT3 passing through the fifth insulating layer 119, the fourth insulating layer 117, the third insulating layer 115, and the second insulating layer 113. The connection electrode CM may be connected to the second electrode EE2 of the first thin-film transistor TFT1 through a contact hole.

Each of the second wiring WL2 and the connection electrode CM may include molybdenum (Mo), aluminum (Al), copper (Cu), or titanium (Ti), and may have a single or multi-layer structure.

A sixth insulating layer 123 may be provided on the substrate 100 to cover the second wiring WL2. The sixth insulating layer 123 may be formed of silicon oxide (SiO₂), silicon nitride (SiNₓ), silicon oxynitride (SiON), aluminum oxide (Al₂O₃), titanium oxide (TiO₂), tantalum oxide (Ta₂O₅), or hafnium oxide (HfO₂). Alternatively, the sixth insulating layer 123 may be formed of an organic material such as acryl, benzocyclobutene (BCB), or hexamethyldisiloxane (HMDSO). When the sixth insulating layer 123 is formed of an organic insulating material, the sixth insulating layer 123 may planarize a top surface of a protective film covering the first and second thin-film transistors TFT1 and TFT2.

The sixth insulating layer 123 may include a via hole VH that extends to the connection electrode CM. The connection electrode CM and a pixel electrode 310 of the organic light-emitting diode OLED located on the sixth insulating layer 123 may be connected to each other through the via hole VH.

The organic light-emitting diode OLED including the pixel electrode 310, a counter electrode 330, and an intermediate layer 320 located between the pixel electrode 310 and the counter electrode 330 and including an emission layer may be located on the sixth insulating layer 123. The pixel electrode 310 may contact the connection electrode CM through the via hole VH provided in the sixth insulating layer 123 to be connected to the first thin-film transistor TFT1.

The pixel electrode 310 may be a transparent electrode or a reflective electrode. When the pixel electrode 310 is a transparent electrode, the pixel electrode 310 may include ITO, IZO, ZnO, or In203, and when the pixel electrode 310 is a reflective electrode, the pixel electrode 310 may include a reflective film formed of Ag, Mg, Al, Pt, Pd, Au, Ni, Nd, Ir, Cr, or a compound thereof and a transparent film formed of ITO, IZO, ZnO, or In2O3. In some embodiments, the pixel electrode 310 may have a structure including ITO/Ag/ITO.

A pixel-defining film 125 may be located on the sixth insulating layer 123. The pixel-defining film 125 defines a pixel by having an opening corresponding to each pixel, that is, an opening 125OP that extends to at least a central portion of the pixel electrode 310. Also, the pixel-defining film 125 increases a distance between an edge of the pixel electrode 310 and the counter electrode 330 over the pixel electrode 310 to prevent an arc or the like from occurring at the edge of the pixel electrode 310. The pixel-defining film 125 may be formed of an organic material such as polyimide or hexamethyldisiloxane (HMDSO).

The intermediate layer 320 of the organic light-emitting diode may include a low molecular weight material or a high molecular weight material. When the intermediate layer 320 includes a low molecular weight material, the intermediate layer 320 may have a single or stacked structure in which a hole injection layer (HIL), a hole transport layer (HTL), an organic emission layer (EML), an electron transport layer (ETL), and an electron injection layer (EIL) are stacked, and may include any of various organic materials such as copper phthalocyanine (CuPc), N,N′-Di(napthalene-1-yl)-N,N′-diphenyl-benzidine (NPB), or tris-8-hydroxyquinoline aluminum (Alq3). These layers may be formed by using vacuum deposition.

When the intermediate layer 320 includes a high molecular weight material, the intermediate layer 320 may have a structure including an HTL and an EML. In this case, the HTL may include poly (3,4-ethylenedioxythiophene) (PEDOT), and the EML may include a polymer material such as a polyphenylene vinylene (PPV)-based material or a polyfluorene-based material. The intermediate layer 320 may be formed by using screen printing, inkjet printing, laser-induced thermal imaging (LITI), or the like.

The intermediate layer 320 is not necessarily limited thereto, and may have any of various structures. The intermediate layer 320 may include a layer that is integrally formed over a plurality of pixel electrodes 310, or may include a layer that is patterned to correspond to each of the plurality of pixel electrodes 310.

The counter electrode 330 may face the pixel electrode 310 with the intermediate layer 320 therebetween. That is, the counter electrode 330 may be integrally formed in a plurality of organic light-emitting diodes and may correspond to the plurality of pixel electrodes 310. That is, the pixel electrode 310 may be patterned for each sub-pixel, and the counter electrode 330 may be formed so that a common voltage is applied to all pixels. The counter electrode 330 may be a transparent electrode or a reflective electrode. Holes and electrons injected from the pixel electrode 310 and the counter electrode 330 of the organic light-emitting diode 300 may combine in the emission layer of the intermediate layer 320 to generate light.

A thin-film encapsulation layer (not shown) may be further located on the organic light-emitting diode 300 to seal the organic light-emitting diode 300. The thin-film encapsulation layer may be provided by stacking at least one inorganic encapsulation layer and at least one organic encapsulation layer. For example, the thin-film encapsulation layer may be provided in a structure in which one organic encapsulation layer is sandwiched between two inorganic encapsulation layers.

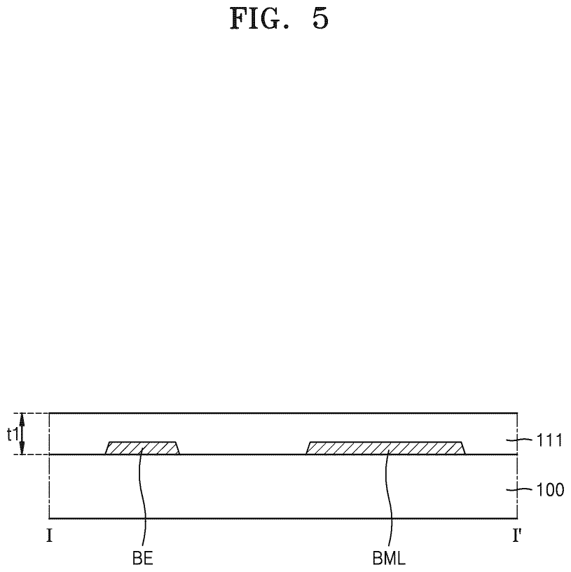

FIGS. 5 to 14 are cross-sectional views schematically illustrating parts of a process of manufacturing a display apparatus, according to an embodiment.

Referring to FIG. 5, the lower electrode BE and the lower conductive layer BML are formed on the substrate 100. Each of the lower electrode BE and the lower conductive layer BML may include molybdenum (Mo), aluminum (Al), copper (Cu), or titanium (Ti), and may have a single or multi-layer structure. Each of the lower electrode BE and the lower conductive layer BML may be formed by using any of various deposition methods such as sputtering, chemical vapor deposition (CVD) or plasma-enhanced vapor deposition (PECVD) and then may be patterned.

Next, the first insulating layer 111 is formed on an entire surface of the substrate 100 to cover the lower electrode BE and the lower conductive layer BML. The first insulating layer 111 may include an inorganic material such as oxide or nitride, an organic material, or a combination of an organic material and an inorganic material, and may have a single or multi-layer structure including an inorganic material and an organic material. In some embodiments, the first insulating layer 111 may be formed of silicon oxide (SiO₂), silicon nitride (SiN_{X}), or silicon oxynitride (SiOₓN_{y}).

The first insulating layer 111 may be formed by using any of various deposition methods such as sputtering, chemical vapor deposition (CVD), or plasma-enhanced vapor deposition (PECVD). The thickness t1 of the first insulating layer 111 may be set by considering a channel length of a second thin-film transistor. The thickness t1 of the first insulating layer 111 may be hundreds to thousands of Å.

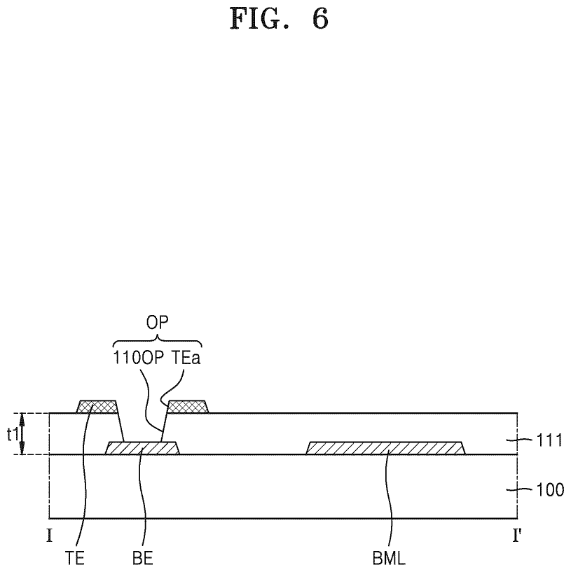

Referring to FIG. 6, after the upper electrode TE is formed on the first insulating layer 111, an opening TEa passing through a central portion of the upper electrode TE and the opening 111OP through which a central portion of the lower electrode BE in the first insulating layer is exposed are formed.

The upper electrode TE may be formed on the first insulating layer 111 by using any of various deposition methods such as sputtering, chemical vapor deposition (CVD), or plasma-enhanced vapor deposition (PECVD) and then may be patterned. The upper electrode TE may be formed to overlap the lower electrode BE.

Next, an opening OP passing through the central portion of the upper electrode TE and the first insulating layer 111 is formed. An opening TEa of the upper electrode TE and the opening 111OP of the first insulating layer 111 overlap each other. The opening 111OP of the first insulating layer 111 may expose a top surface of the lower electrode BE.

To form the opening TEa of the upper electrode TE and the opening 111OP of the first insulating layer 111, a photoresist pattern may be formed through a mask process and a process of etching a portion corresponding to the openings may be performed.

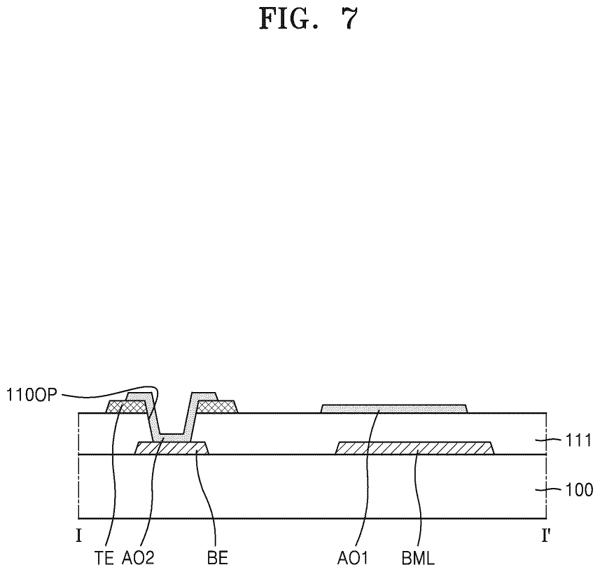

Referring to FIG. 7, the first semiconductor layer AO1 and the second semiconductor layer AO2 are formed on the first insulating layer 111. Each of the first semiconductor layer AO1 and the second semiconductor layer AO2 may be formed of an oxide semiconductor, and may be formed by using any of various deposition methods such as sputtering, chemical vapor deposition (CVD), or plasma-enhanced vapor deposition (PECVD) and then may be patterned.

The first semiconductor layer AO1 may be formed to at least partially overlap the lower conductive layer BML. The second semiconductor layer AO2 may be located in the opening 111OP defined in the first insulating layer 111 to contact the lower electrode BE. The second semiconductor layer AO2 may extend from the inside of the opening 111OP to a top surface of the upper electrode TE. A central portion of the second semiconductor layer AO2 may contact the lower electrode BE and a peripheral portion of the second semiconductor layer AO2 may contact the upper electrode TE.

The first semiconductor layer AO1 may be formed substantially parallel to a top surface of the substrate 100 to form a horizontal channel. The second semiconductor layer AO2 may be formed at a certain angle with respect to the top surface of the substrate 100 to form a vertical channel.

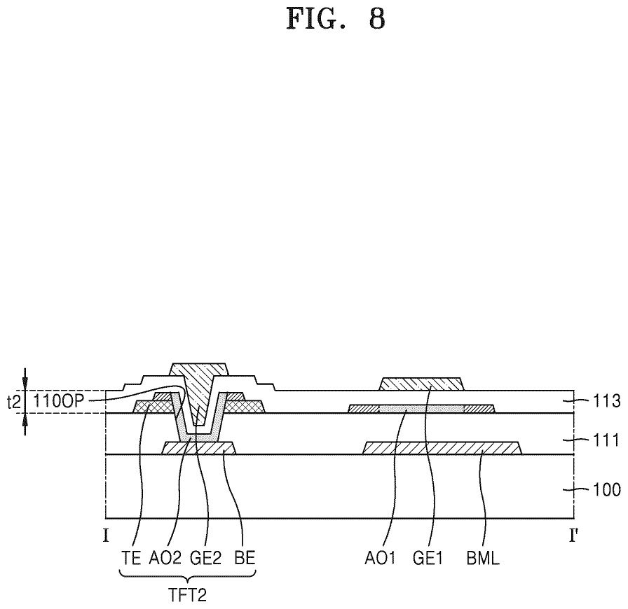

Referring to FIG. 8, the second insulating layer 113 is formed on the substrate 100 to cover the first semiconductor layer AO1 and the second semiconductor layer AO2.

The second insulating layer 113 may be formed of an inorganic insulating material, and may be formed by using any of various deposition methods such as sputtering, chemical vapor deposition (CVD), or plasma-enhanced vapor deposition (PECVD). The thickness t2 of the second insulating layer 113 may be less than the thickness t1 of the first insulating layer 111. The thickness t2 of the second insulating layer 113 may be determined so that a part of the second insulating layer 113 is located in the opening 111OP of the first insulating layer 111.

Next, the first gate electrode GE1 and the second gate electrode GE2 are formed on the second insulating layer 113. Each of the first gate electrode GE1 and the second gate electrode GE2 may be formed of a conductive material, and may be formed by using any of various deposition methods such as sputtering, chemical vapor deposition (CVD), or plasma-enhanced vapor deposition (PECVD) and then may be patterned.

The first gate electrode GE1 may be formed to overlap a central portion of the first semiconductor layer AO1. The second gate electrode GE2 may overlap a central portion of the second semiconductor layer AO2 and may be formed so that at least a part of the second gate electrode GE2 is located in the opening 111OP of the first insulating layer 111.

A portion of the first semiconductor layer AO1 not overlapping the first gate electrode GE1 may be a source region or a drain region. A portion of the second semiconductor layer AO2 not overlapping the second gate electrode GE2 may be a source region or a drain region. Also, a portion of the second semiconductor layer AO2 directly contacting the lower electrode BE may be a source region or a drain region. The source region or the drain region may be a region that is made conductive by increasing a carrier concentration in an oxide semiconductor. The source region and the drain region of the first semiconductor layer AO1 and the second semiconductor layer AO2 may be adjusted through plasma treatment. The plasma treatment may be performed by using hydrogen (H)-based gas, fluorine (F)-based gas, nitrogen gas, or a combination thereof.

Hydrogen (H2) gas may penetrate into an oxide semiconductor in a thickness direction to increase a carrier concentration and reduce surface resistance. Also, when plasma treatment is performed by using hydrogen gas, oxygen may be removed from a surface and metal oxide may be reduced to reduce surface resistance.

When plasma treatment is performed by using F-based gas is performed, an F component may increase on a surface of an oxide semiconductor and an oxygen component may relatively decrease to form additional carriers on the surface. Accordingly, a carrier concentration may increase and surface resistance may decrease. The F-based gas may be, but is not limited to, CF₄, C₄F₈, NF₃, SF₆, or a combination thereof.

When plasma treatment is performed by using nitrogen gas, annealing may be performed at the same time. In some embodiments, the annealing may be performed at a temperature of about 300° C. to about 400° C. for about 1 to 2 hours.

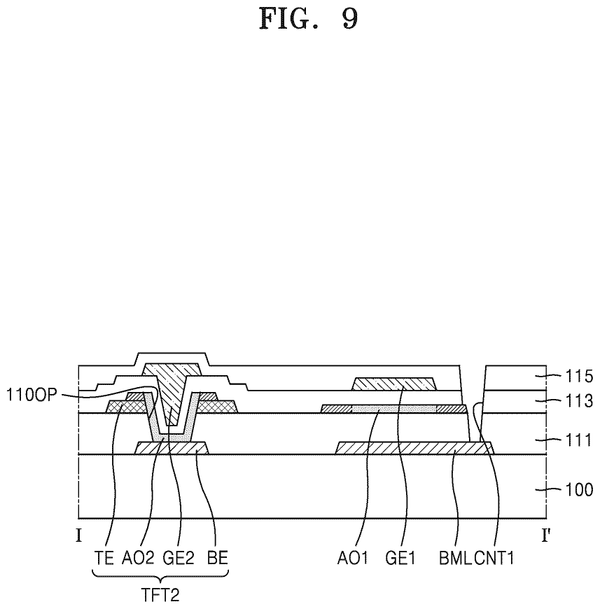

Referring to FIG. 9, the third insulating layer 115 is formed on the entire surface of the substrate 100 to cover the first gate electrode GE1 and the second gate electrode GE2. The third insulating layer 115 may be formed of an inorganic insulating material, and may be formed by using any of various deposition methods such as sputtering, chemical vapor deposition (CVD), or plasma-enhanced vapor deposition (PECVD).

Next, the first contact hole CNT1 passing through the third insulating layer 115, the second insulating layer 113, and the first insulating layer 111 is formed. The first contact hole CNT1 may overlap the lower conductive layer BML and may expose a top surface of the lower conductive layer BML. The first contact hole CNT1 may be provided to expose a side surface of the first semiconductor layer AO1 located on the first insulating layer 111. Alternatively, unlike this, the first contact hole CNT1 may be provided to pass through the first semiconductor layer AO1. To form the first contact hole CNT1, a photoresist pattern may be formed through a mask process and a process of etching a portion corresponding to the first contact hole CNT1 may be performed.

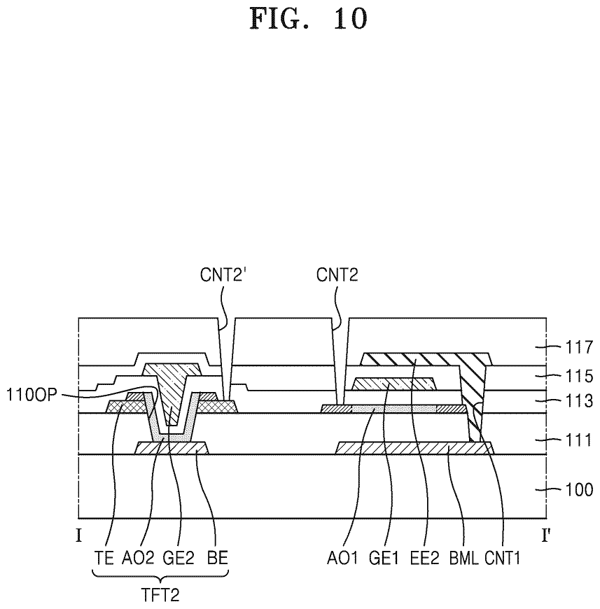

Referring to FIG. 10, the second electrode EE2 may be formed on the third insulating layer 115. The second electrode EE2 may be connected to the lower conductive layer BML and the first semiconductor layer AO1 through the first contact hole CNT1. The second electrode EE2 may be formed of a conductive material, and may be formed by using any of various deposition methods such as sputtering, chemical vapor deposition (CVD), or plasma-enhanced vapor deposition (PECVD) and then may be patterned.

Next, the fourth insulating layer 117 may be formed on the entire surface of the substrate 100 to cover the second electrode EE2. The fourth insulating layer 117 may be formed of an inorganic insulating material, and may be formed by using any of various deposition methods such as sputtering, chemical vapor deposition (CVD), or plasma-enhanced vapor deposition (PECVD).

Next, the second contact holes CNT2 and CNT2′ passing through the fourth insulating layer 117 and the third insulating layer 115 may be formed. To form the second contact holes CNT2 and CNT2′, a photoresist pattern may be formed through a mask process and a process of etching portions corresponding to the second contact holes CNT2 and CNT2′ may be performed. The second contact hole CNT2 may expose a top surface of the first semiconductor layer AO1. The second contact hole CNT2′ may expose a top surface of the upper electrode TE.

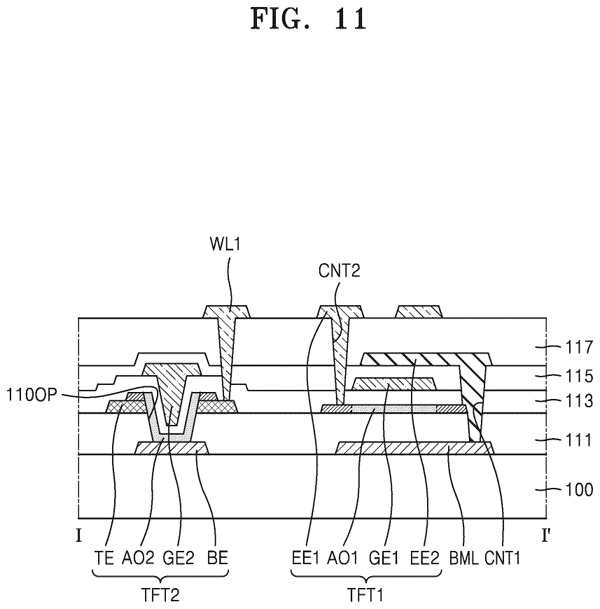

Referring to FIG. 11, the first wiring WL1 and the first electrode EE1 may be formed on the fourth insulating layer 117. The first wiring WL1 may be connected to the upper electrode TE through the second contact hole CNT2′. The first electrode EE1 may be connected to the first semiconductor layer AO1 through the second contact hole CNT2. Each of the first wiring WLI and the first electrode EE1 may be formed of a conductive material, and may be formed by using any of various deposition methods such as sputtering, chemical vapor deposition (CVD), or plasma-enhanced vapor deposition (PECVD) and then may be patterned.

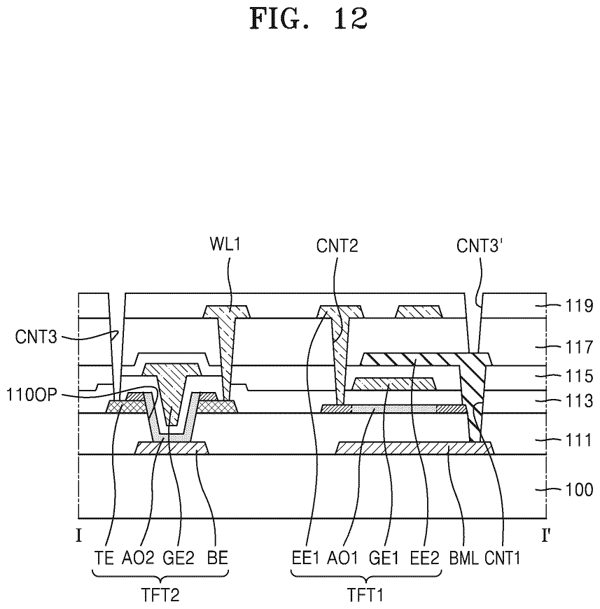

Referring to FIG. 12, the fifth insulating layer 119 may be formed to cover the first wiring WL1 and the first electrode EE1. The fifth insulating layer 119 may be formed of an inorganic insulating material, and may be formed by using any of various deposition methods such as sputtering, chemical vapor deposition (CVD), or plasma-enhanced vapor deposition (PECVD).

Next, the third contact holes CNT3 and CNT3′ passing through the fifth insulating layer 119, the fourth insulating layer 117, and the third insulating layer 115 or passing through the fifth insulating layer 119 and the fourth insulating layer 117 may be formed. To form the third contact holes CNT3 and CNT3′, a photoresist pattern may be formed through a mask process and a process of etching portions corresponding to the third contact holes CNT3 and CNT3′ may be performed. The third contact hole CNT3 may expose a top surface of the upper electrode TE. The third contact hole CNT3′ may expose a top surface of the second electrode EE2.

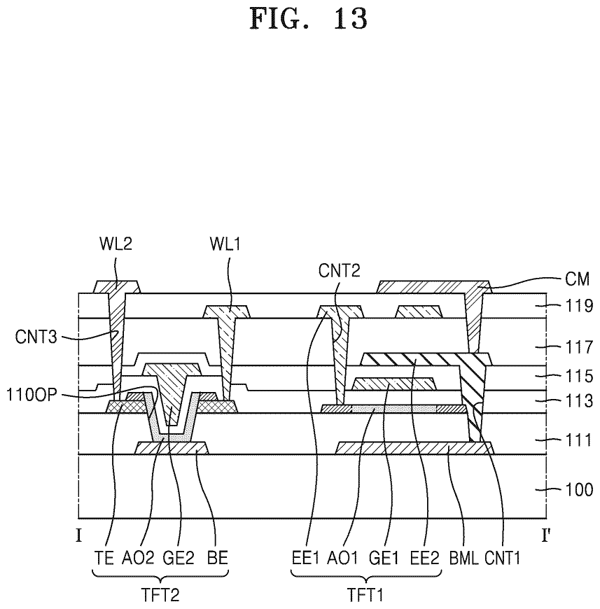

Referring to FIG. 13, the second wiring WL2 and the connection electrode CM may be formed on the fifth insulating layer 119. The second wiring WL2 may be connected to the upper electrode TE through the third contact hole CNT3. The connection electrode CM may be connected to the second electrode EE2 through the third contact hole CNT3′. Each of the second wiring WL2 and the connection electrode CM may be formed of a conductive material, and may be formed by using any of various deposition methods such as sputtering, chemical vapor deposition (CVD), or plasma-enhanced vapor deposition (PECVD) and then may be patterned.

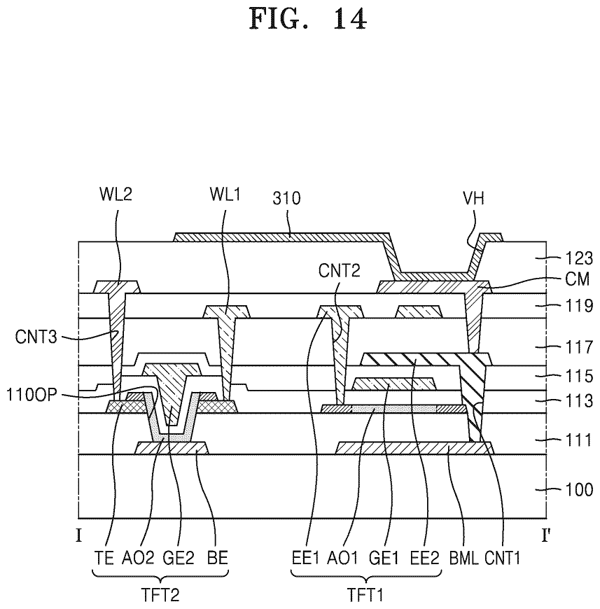

Referring to FIG. 14, the sixth insulating layer 123 may be formed to cover the second wiring WL2 and the connection electrode CM. The sixth insulating layer 123 may include the via hole VH that extends to the connection electrode CM. The sixth insulating layer 123 may be formed of an organic insulating material, and may be formed by applying, developing, and curing an organic insulating material.

Next, the pixel electrode 310 may be formed on the sixth insulating layer 123. The pixel electrode 310 may be formed of a conductive material, and may be formed by using any of various deposition methods and then may be patterned.

Next, a display apparatus may be completed by performing a subsequent process according to a type of a light-emitting element.

In a method of manufacturing a display apparatus according to an embodiment, because the first gate electrode GE1 of the first thin-film transistor TFT1 that is a horizontal-type transistor and the second gate electrode GE2 of the second thin-film transistor TFT2 that is a vertical-type transistor may be simultaneously formed in the same process, a display apparatus that minimizes process costs and has high integration may be provided.

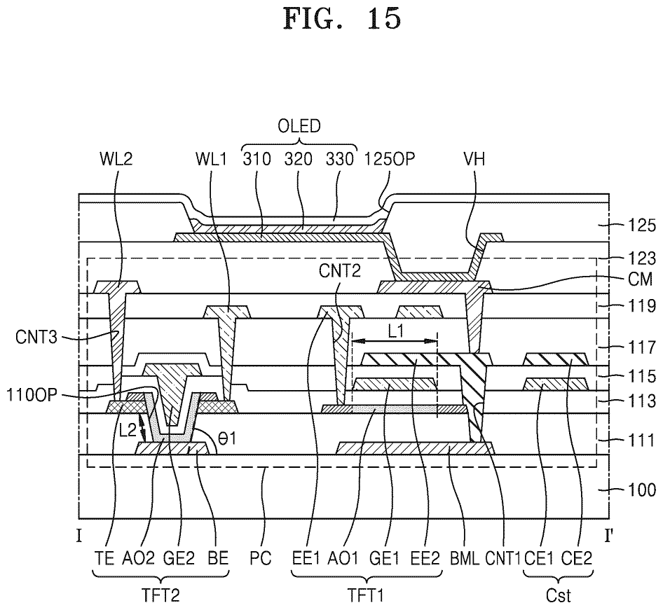

FIG. 15 is a cross-sectional view schematically illustrating a display apparatus, according to an embodiment. In FIG. 15, the same members as those in FIG. 4 are denoted by the same reference numerals.

Referring to FIG. 15, in the display apparatus according to an embodiment, the pixel circuit PC may be located on the substrate 100 and the organic light-emitting diode OLED may be located as a light-emitting element connected to the pixel circuit PC.

The pixel circuit PC according to the present embodiment includes the first thin-film transistor TFT1 that is a horizontal-type transistor and the second thin-film transistor TFT2 that is a vertical-type transistor.

In the present embodiment, the pixel circuit PC may further include a storage capacitor Cst. The storage capacitor Cst may include a first capacitor electrode CE1 and a second capacitor electrode CE2, and the third insulating layer 115 may be located between the first capacitor electrode CE1 and the second capacitor electrode CE2.

The first capacitor electrode CE1 may be formed of the same material on the same layer as the first gate electrode GE1 of the first thin-film transistor TFT1 and the second gate electrode GE2 of the second thin-film transistor TFT2. The first capacitor electrode CE1 may be located on the second insulating layer 113.

The second capacitor electrode CE2 may be formed of the same material on the same layer as the second electrode EE2 of the first thin-film transistor TFT1. The second capacitor electrode CE2 may be located on the third insulating layer 115.

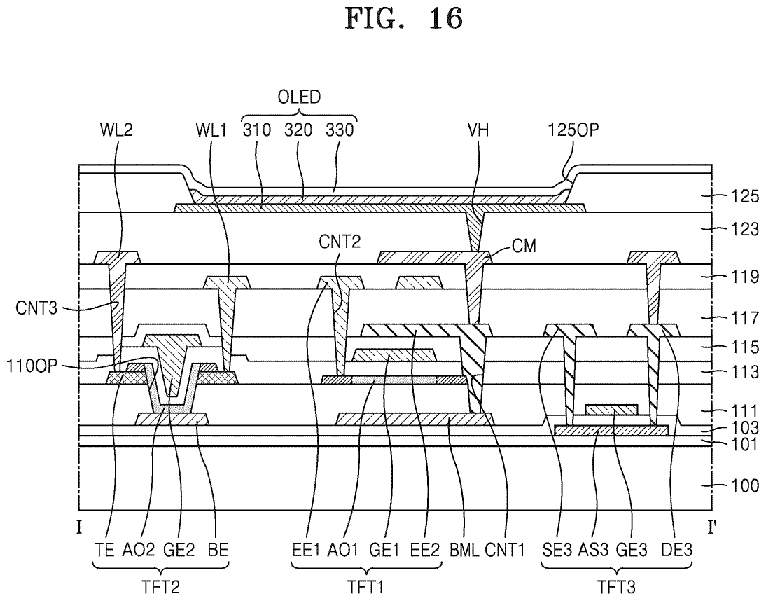

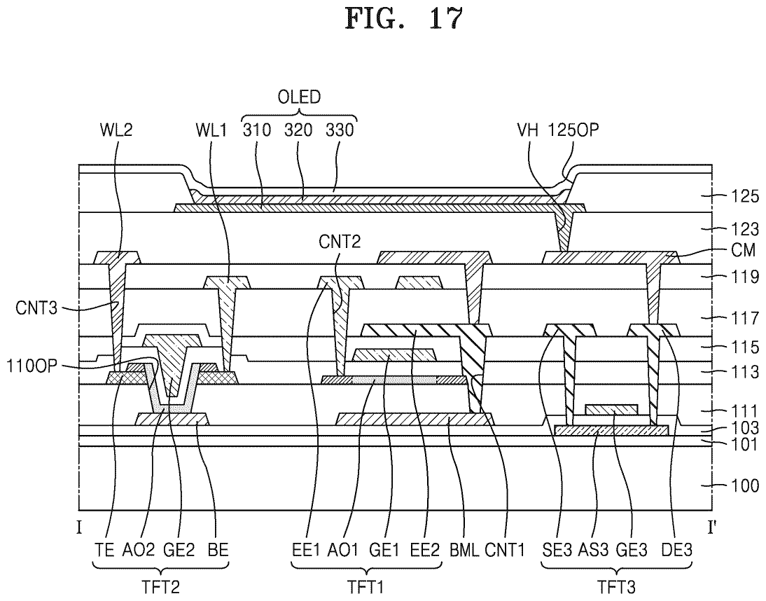

FIGS. 16 and 17 are cross-sectional views schematically illustrating a display apparatus, according to embodiments. In FIG. 15, the same members as those in FIG. 4 are denoted by the same reference numerals.

Referring to FIGS. 16 and 17, in the display apparatus according to an embodiment, the pixel circuit PC may be located on the substrate 100, and the organic light-emitting diode OLED may be located as a light-emitting element connected to the pixel circuit PC.

The pixel circuit PC according to the present embodiment may include the first thin-film transistor TFT1 that is a horizontal-type transistor and the second thin-film transistor TFT2 that is a vertical-type transistor. Each of the first thin-film transistor TFT1 and the second thin-film transistor TFT2 may be a transistor including an oxide semiconductor.

Referring to FIGS. 16 and 17, the pixel circuit PC may further include a third thin-film transistor TFT3.

The third thin-film transistor TFT3 may be a transistor including a silicon semiconductor. The third thin-film transistor TFT3 may include a third semiconductor layer AS3 including a silicon semiconductor and a third gate electrode GE3 insulated from the third semiconductor layer AS3. The third thin-film transistor TFT3 may include a source electrode SE3 and a drain electrode DE3.

When the third thin-film transistor TFT3 is included, a buffer layer 101 and a gate insulating layer 103 may be further provided on the substrate 100.

The buffer layer 101 may be located on the substrate 100, and may reduce or prevent penetration of a foreign material, moisture, or external air from the bottom of the substrate 100 and may planarize the substrate 100. The buffer layer 101 may include an inorganic material such as oxide or nitride, an organic material, or a combination of an organic material and an inorganic material, and may have a single or multi-layer structure including an inorganic material and an organic material. In some embodiments, the buffer layer 101 may be formed of silicon oxide (SiO₂), silicon nitride (SiN_{X}), or silicon oxynitride (SiOₓN_{y}).

The third semiconductor layer AS3 including a silicon semiconductor may be located on the buffer layer 101, and the third semiconductor layer AS3 may include polysilicon or amorphous silicon. The third semiconductor layer AS3 may include a channel region, and a source region and a drain region doped with impurities.

The gate insulating layer 103 may be provided to cover the third semiconductor layer AS3. The gate insulating layer 103 may include an inorganic insulating material such as silicon oxide (SiO₂), silicon nitride (SiNₓ), silicon oxynitride (SiOₓN_{y}), aluminum oxide (Al₂O₃), or titanium oxide (TiO₂). The gate insulating layer 103 may have a single or multi-layer structure including the inorganic insulating material.

The third gate electrode GE3 is located on the gate insulating layer 103 to overlap the third semiconductor layer AS3. The third gate electrode GE3 may be formed of the same material on the same layer as the lower conductive layer BML and the lower electrode BE of the second thin-film transistor. The first insulating layer 111, the second insulating layer 113, and the third insulating layer 115 may be located on the third gate electrode GE3.

The source electrode SE3 and the drain electrode DE3 may be formed of the same material on the same layer as the second electrode EE2 of the first thin-film transistor. The source electrode SE3 and the drain electrode DE3 may be located on the third insulating layer 115.

When the third thin-film transistor TFT3 is provided, the third thin-film transistor TFT3 may not be directly connected to the pixel electrode 310 as shown in FIG. 16. Alternatively, as shown in FIG. 17, the third thin-film transistor TFT3 may be directly connected to the pixel electrode 310.

In some embodiments, because the third thin-film transistor TFT3 includes polycrystalline silicon having excellent reliability, the third thin-film transistor TFT3 may be provided as a driving thin-film transistor. In this case, the first thin-film transistor TFT1 and the second thin-film transistor TFT2 may function as switching transistors. However, the disclosure is not limited thereto. Various modifications may be made. For example, the second thin-film transistor TFT2 that is a horizontal-type thin-film transistor may function as a driving thin-film transistor.

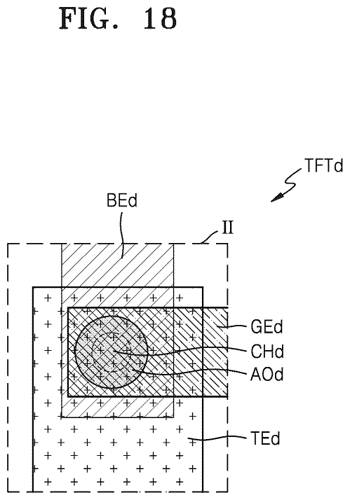

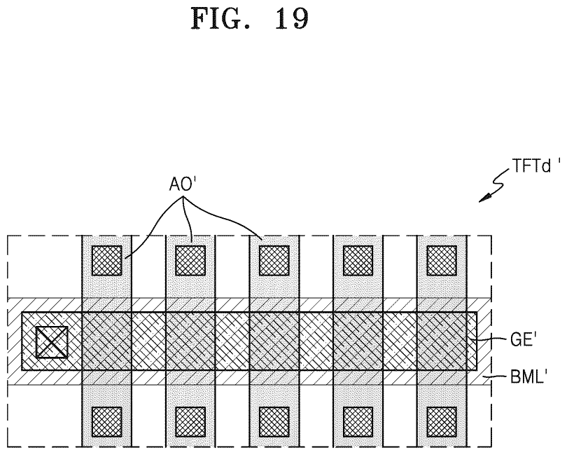

FIG. 18 is a plan view schematically illustrating a part of a display apparatus, according to an embodiment. FIG. 19 is a plan view schematically illustrating a comparative example with respect to the embodiment of FIG. 18. In detail, FIG. 18 illustrates a portion II, which is a peripheral area, of FIG. 1.

Referring to FIG. 18, an embodiment may include a built-in driving thin-film transistor TFTd provided as a vertical-type transistor in a peripheral area.

The built-in driving thin-film transistor TFTd may be a transistor that provides a scan signal or an emission control signal. The built-in driving thin-film transistor TFTd includes a lower electrode BEd, an upper electrode TEd, a semiconductor layer AOd, and a gate electrode GE. An edge of the semiconductor layer AOd may contact the upper electrode TEd and a central portion of the semiconductor layer AOd may contact the lower electrode BEd to form a vertical channel region CHd in the semiconductor layer AOd.

Because a vertical-type transistor may generate 5 times more current per unit width than a horizontal-type transistor, the area of a peripheral area may be reduced by employing the built-in driving thin-film transistor TFTd that is a vertical-type transistor.

FIG. 19 illustrates an example where a built-in driving thin-film transistor TFTd′ that is a horizontal-type transistor is formed. The built-in driving thin-film transistor TFTd′ includes a gate electrode GE′ connected to a lower conductive layer BML′ through a contact hole and includes semiconductor layers AO′ overlapping the gate electrode GE′.

To construct the built-in driving thin-film transistor TFTd′ that is a horizontal-type transistor and generates the same amount of current as in FIG. 18, five semiconductor layers AO′ should be provided in parallel, thereby requiring a wide area.

As described above, according to embodiments, a display apparatus that has high reliability, high integration, and may display a high-quality image by employing both a vertical channel thin-film transistor and a horizontal channel thin-film transistor may be provided. However, the embodiments are examples and do not limit the effects of the disclosure.

It should be understood that embodiments described herein should be considered in a descriptive sense only and not for purposes of limitation. Descriptions of features or aspects within each embodiment should typically be considered as available for other similar features or aspects in other embodiments. While embodiments have been described with reference to the figures, it will be understood by one of ordinary skill in the art that various changes in form and details may be made therein without departing from the spirit and scope as defined by the following claims.

What is claimed is:

1. A display apparatus comprising:
a substrate;
a first thin-film transistor located on the substrate and comprising a first semiconductor layer and a first gate electrode;
a second thin-film transistor located on the substrate and comprising a second semiconductor layer, a second gate electrode, a lower electrode, and an upper electrode; and
a lower conductive layer located between the substrate and the first semiconductor layer,
wherein a first angle between a channel region of the first semiconductor layer and the substrate is different from a second angle between a channel region of the second semiconductor layer and the substrate,
wherein the first gate electrode and the second gate electrode are located on a same layer, and
the lower electrode and the lower conductive layer are located on a same layer.

2. The display apparatus of claim 1, wherein the first angle is 0° to 5°, and the second angle is 20° to 90°.

3. The display apparatus of claim 1, wherein the lower electrode of the second thin-film transistor is connected to the lower conductive layer.

4. The display apparatus of claim 3, wherein a central portion of the second semiconductor layer is connected to the lower electrode, and a peripheral portion of the second semiconductor layer is connected to the upper electrode.

5. The display apparatus of claim 3, further comprising a first insulating layer located between the lower electrode and the upper electrode,
wherein the first insulating layer comprises a first opening that extends to the lower electrode, and at least a part of the second semiconductor layer is located in the first opening.

6. The display apparatus of claim 5, further comprising a second insulating layer covering the second semiconductor layer,
wherein a thickness of the second insulating layer is less than a thickness of the first insulating layer.

7. The display apparatus of claim 1, further comprising a storage capacitor comprising a first capacitor electrode and a second capacitor electrode,
wherein the first capacitor electrode is located on a same layer as the first gate electrode and the second gate electrode.

8. The display apparatus of claim 1, wherein each of the first semiconductor layer and the second semiconductor layer comprises an oxide semiconductor.

9. The display apparatus of claim 1, further comprising a third thin-film transistor located on the substrate and comprising a third semiconductor layer and a third gate electrode,
wherein each of the first semiconductor layer and the second semiconductor layer comprises an oxide semiconductor, and
the third semiconductor layer comprises a silicon semiconductor.

10. The display apparatus of claim 9, wherein the third gate electrode is located above the third semiconductor layer and below a first insulating layer, and
the first semiconductor layer is located above the first insulating layer.

11. A display apparatus comprising:
a substrate;
a first insulating layer located on the substrate and comprising a first opening;
a first thin-film transistor comprising a first semiconductor layer and a first gate electrode, the first semiconductor layer being located on a top surface of the first insulating layer;
a second thin-film transistor comprising a second semiconductor layer at least partially located in the first opening, a lower electrode located under the first insulating layer, an upper electrode located over the first insulating layer, and a second gate electrode located on the second semiconductor layer; and
a second insulating layer covering the first semiconductor layer and the second semiconductor layer,
wherein the first gate electrode and the second gate electrode are located on the second insulating layer.

12. The display apparatus of claim 11, wherein an angle between an inner wall of the first opening and a top surface of the substrate is 20° to 90°.

13. The display apparatus of claim 11, further comprising a lower conductive layer located between the substrate and the first semiconductor layer,
wherein the lower electrode is located on a same layer as the lower conductive layer.

14. The display apparatus of claim 11, wherein a central portion of the second semiconductor layer is connected to the lower electrode, and a peripheral portion of the second semiconductor layer is connected to the upper electrode.

15. The display apparatus of claim 11, wherein a thickness of the second insulating layer is less than a thickness of the first insulating layer.

16. The display apparatus of claim 11, wherein each of the first semiconductor layer and the second semiconductor layer comprises an oxide semiconductor.

17. The display apparatus of claim 11, further comprising a storage capacitor comprising a first capacitor electrode and a second capacitor electrode,
wherein the first capacitor electrode is located on a same layer as the first gate electrode and the second gate electrode.

18. The display apparatus of claim 11, further comprising a third thin-film transistor located on the substrate and comprising a third semiconductor layer and a third gate electrode,
wherein each of the first semiconductor layer and the second semiconductor layer comprises an oxide semiconductor, and
the third semiconductor layer comprises a silicon semiconductor.

19. The display apparatus of claim 18, wherein the third gate electrode is located above the third semiconductor layer and below a first insulating layer, and
the first semiconductor layer is located above the first insulating layer.

20. The display apparatus of claim 11, wherein the substrate comprises a display area and a peripheral area around the display area,
wherein the display apparatus further comprises a built-in driving thin-film transistor located in the peripheral area,
wherein the built-in driving thin-film transistor is a vertical-type thin-film transistor.
